(19) United States
(12) Patent Application Publication
(10) Pub. No.: US 2026/0253654 A1
(43) Pub. Date: Aug. 27, 2026

(54) SEMICONDUCTOR DEVICE(S) AND MEMORY SYSTEM(S)

(71) Applicant: SK hynix Inc., Icheon-si Gyeonggi-do (KR)

(72) Inventors: Jun Yeol JEON, Icheon-si Gyeonggi-do (KR); Ki Up KIM, Icheon-si Gyeonggi-do (KR); Eun Je KIM, Icheon-si Gyeonggi-do (KR)

(73) Assignee: SK hynix Inc., Icheon-si Gyeonggi-do (KR)

(21) Appl. No.: 19/411,840

(22) Filed: Dec. 8, 2025

(30) Foreign Application Priority Data
Feb. 24, 2025 (KR) 10-2025-0023975

(51) Int. Cl. G11C 17/18; G11C 17/16

(52) U.S. Cl. CPC G11C 17/18; G11C 17/16

(57) ABSTRACT

A semiconductor device includes a fuse array configured to output input fuse data for a bootup operation and a re-bootup operation, an update control circuit configured to generate a bank fuse latch enable signal, a row column clock signal, and a bank fuse latch clock signal based on a bootup clock signal to perform the bootup operation and the re-bootup operation, and mask a fuse latch reset signal and a fuse latch clock signal when a test set pulse signal is activated to perform the re-bootup operation, and a test mode fuse latch configured to latch the input fuse data based on the fuse latch clock signal and the fuse latch reset signal, and output the latched input fuse data as output fuse data in the bootup operation.

### CROSS REFERENCE TO RELATED APPLICATIONS

The present application claims priority under 35 U.S.C §119(a) to Korean Patent Application No. 10-2025-0023975, filed in the Korean Intellectual Property Office on February 24, 2025, the entire contents of which application is incorporated herein by reference.

### BACKGROUND

### 1. Technical Field

The present disclosure generally relates to semiconductor devices, and more particularly, to semiconductor devices including array rupture e-fuses (AREs) and memory systems including the semiconductor devices including AREs.

### 2. Related Art

Semiconductor devices use fuses to store information used for various internal control operations, such as various setting information and repair information. In typical fuses, data is distinguished depending on whether the fuse is cut by a cutting means, for example, laser. Accordingly, while it is possible to program the fuse in a wafer state, once the wafer is mounted inside a package, it becomes impossible to program the fuse. E-fuses are employed to overcome such drawbacks.

### SUMMARY

An embodiment of the present disclosure provides a semiconductor device that includes a fuse array configured to output input fuse data for a bootup operation and a re-bootup operation. The semiconductor device includes an update control circuit configured to generate a bank fuse latch enable signal, a row column clock signal, and a bank fuse latch clock signal based on a bootup clock signal to perform the bootup operation and the re-bootup operation. The update control circuit is configured to mask a fuse latch reset signal and a fuse latch clock signal when a test set pulse signal is activated to perform the re-bootup operation. The semiconductor device includes a test mode fuse latch configured to latch the input fuse data based on the fuse latch clock signal and the fuse latch reset signal and output the latched input fuse data as output fuse data in the bootup operation.

An embodiment of the present disclosure provides a memory system that includes an interposer stacked over a substrate, and a memory device and a processor that are stacked over the interposer and connected to each other through wiring formed in the interposer. The memory device includes a base die and a plurality of core dies. Each of the plurality of core dies receive a control signal from the base die to perform a bootup operation and a re-bootup operation. Each of the plurality of core dies mask a signal for resetting trimming information of an internal voltage during the re-bootup operation to maintain a voltage level of the internal voltage.

### BRIEF DESCRIPTION OF THE DRAWINGS

FIG. 1 illustrates a semiconductor device according to an embodiment of the present disclosure.

FIG. 2 illustrates an update control circuit according to an embodiment of the present disclosure.

FIG. 3 illustrates a bootup control circuit according to an embodiment of the present disclosure.

FIG. 4 is a circuit diagram illustrating a bootup control circuit according to an embodiment of the present disclosure.

FIG. 5 illustrates a masking control circuit according to an embodiment of the present disclosure.

FIG. 6 is a circuit diagram illustrating a masking signal control circuit according to an embodiment of the present disclosure.

FIG. 7 is a circuit diagram illustrating a test mode fuse latch control circuit according to an embodiment of the present disclosure.

FIG. 8 is a circuit diagram illustrating a test mode fuse clock control circuit according to an embodiment of the present disclosure.

FIG. 9 is a circuit diagram illustrating a pulse generation circuit according to an embodiment of the present disclosure.

FIG. 10 is a timing diagram illustrating when a masking operation is not performed in a re-bootup operation.

FIG. 11 is a timing diagram during an operation of a semiconductor device according to an embodiment of the present disclosure.

FIG. 12 illustrates a stacked memory system according to an embodiment of the present disclosure.

FIG. 13 illustrates one of a plurality of core dies according to an embodiment of the present disclosure.

FIG. 14 illustrates an update control circuit according to an embodiment of the present disclosure.

FIG. 15 illustrates a bootup control circuit according to an embodiment of the present disclosure.

FIG. 16 illustrates a masking control circuit according to an embodiment of the present disclosure.

### DETAILED DESCRIPTION

In the following description of embodiments, when a parameter is referred to as being “predetermined,” it may be intended to mean that a value of the parameter is determined in advance when the parameter is used in a process or an algorithm. The value of the parameter may be set when the process or the algorithm starts or may be set during a period that the process or the algorithm is executed.

Terms such as “first” and “second” are used to distinguish between various elements and do not imply size, order, priority, quantity, or importance of the elements. For example, a first element may be named as a second element in one example, and the second element may be named as a first element in another example.

When one component is identified as “connected” to another component, the components may be connected directly or through an intervening component between the components. When two components are identified as “directly connected,” one component is directly connected to the other component without an intervening component between the two components.

A logic “high” level and a logic “low” level may be used to describe logic levels of electric signals. A signal at a logic high level is distinguished from a signal at a logic low level. For example, when a signal at a first voltage corresponds to a signal at a logic high level, a signal at a second voltage corresponds to a signal at a logic low level. In an embodiment, the logic high level may be a voltage level that is higher than a voltage level of the logic low level. Logic levels of signals may be different or opposite according to the embodiments. For example, a signal at a logic high level in one embodiment may be at a logic low level in another embodiment, and a signal at a logic low level in one embodiment may be at a logic high level in another embodiment.

"Binary bit set" may refer to a combination of logic levels of bits included in a signal. The binary bit set of the signal may be set differently when a logic level of each of the bits included in the signal is changed. For example, when a signal includes 2 bits, when a logic level of each of the 2 bits included in the signal is "logic low level, logic low level", the binary bit set of the signal may be set to "00", and when a logic level of each of the 2 bits included in the signal is "logic low level, logic high level", the binary bit set of the signal may be set to "01".

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

The e-fuse refers to a fuse that stores data by changing the resistance between a gate and a drain/source of a transistor. In order to recognize the data of the e-fuse, the transistor may be enlarged in size so that the data can be directly recognized without a separate sensing operation, or alternatively, the transistor may be reduced in size and the data of the e-fuse may be recognized by sensing the current flowing through the transistor using an amplifier. However, the transistor constituting the e-fuse is designed with an increased size or an amplifier for amplifying data is provided for each e-fuse, so that the above-mentioned methods impose area limitation.

Recently, in order to overcome the area limitation of e-fuses, a method of implementing the e-fuses in an array to store information used for internal control operations of a semiconductor device has been studied. When the e-fuses are implemented in an array, an amplifier for amplifying the data of the e-fuses may be shared, thereby reducing the entire area.

In the semiconductor memory device industry, a large number of original good dies with no defective memory cells were distributed on a wafer that passed through the semiconductor manufacturing process. However, as the capacity of the semiconductor memory device has gradually increased, it has become difficult to make a semiconductor memory device with no defective memory cells, and there may be little probability that such semiconductor memory devices are manufactured. As a way to overcome this situation, a repair method is used whereby redundancy memory cells are provided in a semiconductor memory device and defective memory cells are replaced with the redundancy memory cells.

In general, when a wafer-level manufacturing process of a semiconductor memory device is completed, a test is performed to determine whether memory cells are normal. After the test, the defective memory cells are replaced with the redundancy memory cells for repair in a wafer state through the repair operation. This is normal repair when the repair operation is performed in the wafer state. There is also post package repair (PPR) that proceeds after the semiconductor memory device is packaged, and it is possible to repair the defective memory cells that are not found in the wafer state but occur after packaging or during the user's memory device use by using the post package repair technology.

The post-package repair (PPR) includes hard post-package repair (hereinafter, referred to as “hard repair”) and soft post-package repair (hereinafter, referred to as “soft repair”). The hard repair means the post-package repair in which the effect of repair is permanently maintained once repaired. The soft repair refers to temporary post package repair in which the effect of repair disappears when the semiconductor memory device is not powered. For example, when a hard repair operation is performed to replace a certain memory cell “X” with a redundancy memory cell “Y”, the memory cell X is permanently replaced by the redundancy memory cell Y. However, when a soft repair operation is performed to replace the memory cell X with the redundancy memory cell Y, the repair operation for the memory cell X is performed whenever new power is supplied to the semiconductor memory device.

Information of a word line ruptured due to the hard repair operation is updated to the fuse set at a memory bank level. A re-bootup operation is performed to update the word line information to the fuse set. However, because even a bias for an internal voltage is temporarily removed by a signal for resetting a fuse latch during the re-bootup operation, there are cases where the voltage level of the internal voltage cannot be specified, such as when a peripheral voltage is used as the internal voltage. Due to the instability of the internal voltage, it becomes difficult to guarantee the stability of the re-bootup operation.

Embodiments of the present disclosure provide semiconductor devices and semiconductor systems capable of stably performing a re-bootup operation following a hard repair operation.

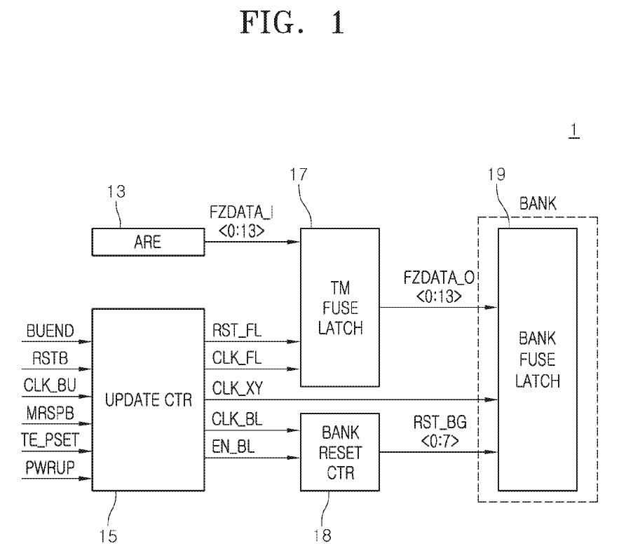

FIG. 1 illustrates a semiconductor device 1 according to an embodiment of the present disclosure.

As shown in FIG. 1, the semiconductor device 1 includes a fuse array 13, an update control circuit 15, a test mode fuse latch 17, a bank reset control circuit 18, and a bank fuse latch 19.

The semiconductor device 1 performs a bootup operation and a re-bootup operation. The bootup operation may be defined as an operation for scanning fuse data for a fail address stored in the fuse array 13 before a memory device (not shown) operates after a power-up operation. That is, the bootup operation may be defined as an operation of transmitting the information of a fuse set included in the fuse array 13 to a redundancy region (not shown) of the memory device before the memory device operates, during the bootup operation. In this case, the power-up operation may be defined as an operation of applying power to the memory device so that the voltage level of a power supply voltage VDD reaches a certain target voltage level. In addition, the re-bootup operation may be defined as an operation of updating row-series information and column-series information ruptured by a hard repair operation when the hard repair operation ends.

The fuse array 13 is electrically connected to the test mode fuse latch 17 and outputs input fuse data FZDATA_I<0:13> to the test mode fuse latch 17. Here, the input fuse data FZDATA_I<0:13> may be trimming information on a voltage level of an internal voltage VPERI. The input fuse data FZDATA_I<0:13> is set to have a logic bit set corresponding to a certain voltage level to trim the internal voltage VPERI to the certain voltage level. For example, a first logic bit set of the input fuse data FZDATA_I<0:13> may correspond to a first voltage level, and a second logic bit set of the input fuse data FZDATA_I<0:13> may correspond to a second voltage level. The fuse array 13 includes a plurality of fuse cell arrays (FSAs). Each of the fuse cell arrays includes a plurality of fuses (FSs). Here, the fuse array 13 may include electrically programmable e-fuses. The input fuse data FZDATA_I<0:13> may be a signal including repair information for row-series and column-series as well as the trimming information for adjusting the voltage level of the internal voltage.

The update control circuit 15 performs a bootup operation. The bootup operation includes an operation of generating a fuse latch clock signal CLK-FL and a fuse latch reset signal RST-FL. Here, the fuse latch reset signal RST_FL is a signal generated at the start of a re-bootup operation for updating the information ruptured by a hard repair, and may be a signal for resetting the test mode fuse latch 17 containing the existing input fuse data FZDATA_I<0:13> and bias trim information. In addition, the fuse latch clock signal CLK_FL may be a clock signal used when updating the existing input fuse data FZDATA_I<0:13> and the bias trim information. The update control circuit 15 generates the fuse latch reset signal RST_FL based on a power-up signal PRWUP. The update control circuit 15 generates the fuse latch clock signal CLK_FL based on a bootup clock signal CLK_BU. The update control circuit 15 delays the bootup clock signal CLK_BU to generate the fuse latch clock signal CLK_FL. The update control circuit 15 outputs the fuse latch reset signal RST_FL and the fuse latch clock signal CLK_FL to the electrically connected test mode fuse latch circuit 17.

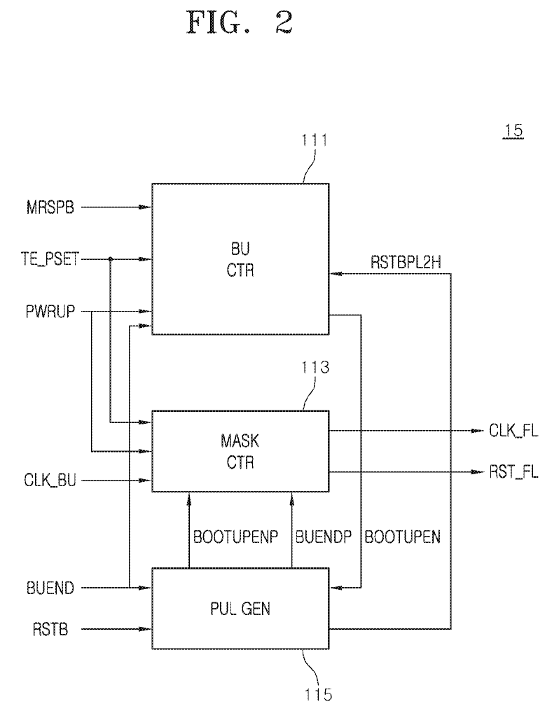

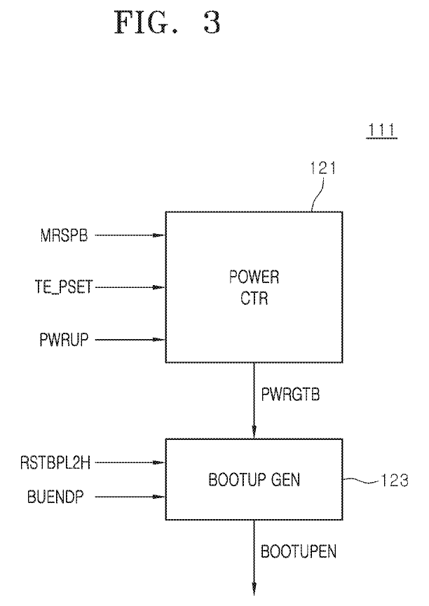

The update control circuit 15 activates the fuse latch reset signal RST_FL during a power-up period when the power-up signal PWRUP is activated. The update control circuit 15 performs a bootup end operation based on a mode register set bar pulse signal MRSPB and a bootup end signal BUEND. The update control circuit 15 deactivates a power control signal (e.g., PWRGTB in FIG. 3), which is a signal necessary for the bootup operation, based on the mode register set bar pulse signal MRSPB, and deactivates a bootup enable signal (e.g., BOOTUPEN in FIG. 2) generated based on the power control signal PWRGTB, thereby ending the bootup operation. Here, the mode register set bar pulse signal MRSPB may be a pulse signal output from a mode register set having data on bootup operation control.

The update control circuit 15 performs a re-bootup operation following a hard-repair operation. The hard-repair operation refers to a post package repair operation whereby the effect of a repair is permanently maintained once repaired. The re-bootup operation may be defined as an operation of updating row-series and column-series information ruptured by the hard-repair operation after the hard-repair operation is completed. The update control circuit 15 performs a masking operation on the fuse latch clock signal CLK_FL and the fuse latch reset signal RST_FL for the re-bootup operation. The update control circuit 15 masks the fuse latch reset signal RST_FL based on a reset bar signal RSTB and a test set pulse signal TE_PSET during the power-up period when the power-up signal PWRUP is activated for the re-bootup operation. The fuse latch reset signal RST_FL is a signal generated at the start of the re-bootup operation for updating information ruptured by the hard-repair, and may be a signal for resetting the test mode fuse latch 17 containing the existing input fuse data FZDATA_I<0:13> and bias trim information. The update control circuit 15 masks the fuse latch clock signal CLK_FL based on the test set pulse signal TE_PSET and a bootup clock signal CLK_BU during the power-up period for the re-bootup operation. Here, the power-up signal PWRUP may refer to a signal that is activated when the voltage level of the power supply voltage VDD reaches a voltage level of a certain target level.

After performing the re-bootup operation, the update control circuit 15 performs a re-bootup end operation of ending the re-bootup operation and the masking operation on the fuse latch clock signal CLK_FL and the fuse latch reset signal RST_FL based on the mode register set bar pulse signal MRSPB and the bootup end signal BUEND. For example, the update control circuit 15 deactivates the power control signal PWRGTB, which is a signal necessary for the re-bootup operation, based on the mode register set bar pulse signal MRSPB, deactivates the bootup enable signal BOOTUPEN generated based on the power control signal PWRGTB, and deactivates the masking signal TMBUMASKB generated based on the bootup enable signal BOOTUPEN, thereby ending the re-bootup operation. The update control circuit 15 ends the re-bootup operation by deactivating the bootup enable signal BOOTUPEN and the masking signal TMBUMASKB based on the bootup end signal BUEND.

The update control circuit 15 generates a bank fuse latch enable signal EN_BL and a bank fuse latch clock signal CLK_BL based on a bootup clock signal CLK_BU. The update control circuit 15 generates a row column clock signal CLK_XY based on the bootup clock signal CLK_BU. The row column clock signal CLK_XY may be defined as a signal for strobing row-series and the column-series repair data included in the output fuse data FZDATA_O<0:13>. The update control circuit 15 outputs the row column clock signal CLK_XY to the electrically connected bank fuse latch 19.

The test mode fuse latch 17 is electrically connected to the fuse array 11 and the update control circuit 15, receives the input fuse data FZDATA_I<0:13> from the fuse array 11, and receives the fuse latch clock signal CLK_FL and the fuse latch reset signal RST_FL from the update control circuit 15. The test mode fuse latch 17 latches the input fuse data FZDATA_I<0:13> based on the fuse latch clock signal CLK_FL and the fuse latch reset signal RST_FL, and outputs the latched input fuse data FZDATA_I<0:13> as output fuse data FZDATA_O<0:13>. The test mode fuse latch 17 may be located in a peripheral region. The test mode fuse latch 17 resets the input fuse data FZDATA_I<0:13> and bias trim information based on the fuse latch reset signal RST_FL and the fuse latch clock signal CLK_FL. More specifically, during the re-bootup operation, when the fuse latch reset signal RST_FL and the fuse latch clock signal CLK_FL are masked, the test mode fuse latch 17 blocks the input of the input fuse data FZDATA_I<0:13>, thereby preventing new fuse data from being latched and maintaining previously stored bias trim information. The test mode fuse latch 17 receives and stores the input fuse data FZDATA_I<0:13>, which is trimming information on the internal voltage VPERI. The test mode fuse latch 17 outputs the latched input fuse data FZDATA_I<0:13> as the output fuse data FZDATA_O<0:13>.

The bank reset control circuit 18 is electrically connected to the update control circuit 15 and receives the bank fuse latch clock signal CLK_BL and the bank fuse latch enable signal EN_BL from the update control circuit 15. The bank reset control circuit 18 generates a bank fuse latch reset signal RST_BG<0:7> based on the bank fuse latch clock signal CLK_BL and the bank fuse latch enable signal EN_BL. The bank fuse latch clock signal CLK_BL may be defined as a signal for controlling reset of the bank fuse latch 19 for each bank group. The bank fuse latch enable signal EN_BL may be defined as a flag signal for notifying that a certain period corresponds to a period in which column-series and row-series trimming information on the bank fuse latch 19 is updated, among periods in which the re-bootup operation and the bootup operation are performed. The bank reset control circuit 18 may be located in the peripheral region. The bank reset control circuit 18 generates the bank fuse latch reset signal RST_BG<0:7> based on the bank fuse latch clock signal CLK_BL during a period when the trimming information is updated based on the bank fuse latch enable signal EN_BL. The bank fuse latch reset signal RST_BG<0:7> is allocated and output for each bank group. The bank fuse latch reset signal RST_BG<0:7> is sequentially output to a plurality of fuse latches in the bank fuse latch 19 located in a bank region. In an embodiment, when a reset operation is performed through the bank fuse latch reset signal RST_BG<0:7> that is sequentially output, instantaneous current consumption may be reduced compared to when the reset operations for updating the plurality of fuse latches are simultaneously performed. The words “simultaneous” and “simultaneously” as used herein with respect to processes mean that the processes take place on overlapping intervals of time. For example, if a first process takes place over a first interval of time and a second process takes place simultaneously over a second interval of time, then the first and second intervals at least partially overlap each other such that there exists a time at which the first and second processes are both taking place.

The bank fuse latch 19 is electrically connected to the update control circuit 15, the test mode fuse latch 17, and the bank reset control circuit 18, receives the row column clock signal CLK_XY from the update control circuit 15, receives the output fuse data FZDATA_O<0:13> from the test mode fuse latch 17, and receives the bank fuse latch reset signal RST_BG<0:7> from the bank reset control circuit 18. A plurality of fuse latches in the bank fuse latch 19 update the output fuse data FZDATA_O<0:13> with repair information based on the row column clock signal CLK_XY and the bank fuse latch reset signal RST_BG<0:7>. The plurality of fuse latches in the bank fuse latch 19 may be located in a bank region. The plurality of fuse latches in the bank fuse latch 19 individually perform a reset operation according to whether the bank fuse latch reset signal RST_BG<0:7> is activated. The row column clock signal CLK_XY is generated in the update control circuit 15 based on the bootup clock signal CLK_BU. The row column clock signal CLK_XY may be defined as a signal for strobing repair data for the row series and the column series included in the output fuse data FZDATA_O<0:13>.

FIG. 2 illustrates an update control circuit 15 included in a semiconductor device according to an embodiment of the present disclosure, for example, as shown in FIG. 1.

As shown in FIG. 2, the update control circuit 15 includes a bootup control circuit 111, a masking control circuit 113, and a pulse generation circuit 115.

The bootup control circuit 111 generates a bootup enable signal BOOTUPEN based on a test set pulse signal TE_PSET and a reset bar pulse signal RSTBPL2H during a power-up period for a re-bootup operation. The bootup control circuit 111 deactivates the bootup enable signal BOOTUPEN when a mode register set bar pulse signal MRSPB is activated, thereby preventing a masking operation for the fuse latch reset signal RST_FL by the bootup enable pulse signal BOOTUPENP from being performed. When the bootup end signal BUEND is activated, the bootup control circuit 111 deactivates the bootup enable signal BOOTUPEN, thereby preventing the masking operation on the fuse latch reset signal RST_FL by a bootup enable pulse signal BOOTUPENP from being performed. Therefore, the re-bootup end operation may be performed.

The masking control circuit 113 generates the fuse latch reset signal RST_FL based on a power-up signal PWRUP for the bootup operation. The masking control circuit 113 generates a fuse latch clock signal CLK_FL based on a bootup clock signal CLK_BU for the bootup operation.

The masking control circuit 113 masks the fuse latch reset signal RST_FL when the test set pulse signal TE_PSET and the bootup enable pulse signal BOOTUPENP are applied during the power-up period for the re-bootup operation. When the bootup enable pulse signal BOOTUPENP is applied during the power-up period for the re-bootup operation, the masking control circuit 113 masks the bootup clock signal CLK_BU to deactivate the fuse latch clock signal CLK_FL.

The pulse generation circuit 115 outputs the bootup end signal BUEND, a reset bar signal RSTB, and the bootup enable signal BOOTUPEN as the bootup end pulse signal BUENDP, the reset bar pulse signal RSTBPL2H, and the bootup enable pulse signal BOOTUPENP, that are pulse signals, respectively.

FIG. 3 illustrates a bootup control circuit 111 according to an embodiment of the present disclosure, for example, as shown in FIG. 2.

As shown in FIG. 3, the bootup control circuit 111 includes a power control circuit 121 and a bootup signal generation circuit 123. The power control circuit 121 generates a power control signal PWRGTB when a test set pulse signal TE_PSET is activated during a power-up period in which a power-up signal PWRUP is activated for a re-bootup operation or a bootup operation. The bootup signal generation circuit 123 performs an operation of generating a bootup enable signal BOOTUPEN when a reset pulse signal RSTBPL2H is activated in a period when the power control signal PWRGTB is activated, in both the re-bootup operation and the bootup operation.

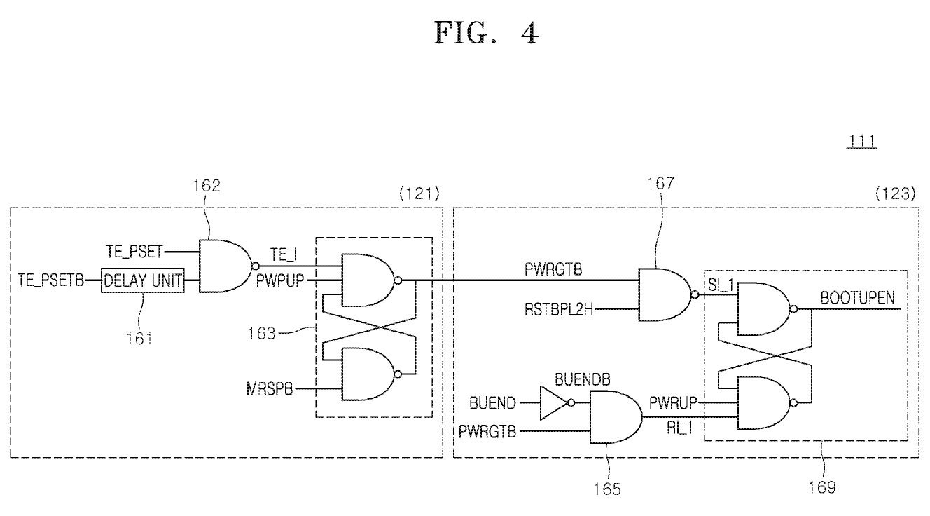

FIG. 4 is a circuit diagram of a bootup control circuit 111 shown in FIG. 3 according to an embodiment of the present disclosure.

As shown in FIG. 4, the bootup control circuit 111 includes the power control circuit 121 and the bootup signal generation circuit 123.

The power control circuit 121 includes a delay unit 161, a NAND gate 162, and an R_S latch 163. The NAND gate 162 performs a NAND operation on the test set pulse signal TE_PSET and a delayed test set bar pulse signal TE_PSETB passed through the delay unit 161 and outputs a pulse-type test input signal TE_I at a logic low level to perform a re-bootup operation. The R_S latch 163 activates the power control signal PWRGTB when the test input signal TE_I is input at a logic low level during a power-up period to perform the re-bootup operation, and deactivates the power control signal PWRGTB when the mode register set bar pulse signal MRSPB is activated.

The bootup signal generation circuit 123 includes an AND gate 165, a NAND gate 167, and an R_S latch 169. The AND gate 165 receives the bootup end bar signal BUENDB and the power control signal PWRGTB and performs an AND operation on the bootup end bar signal BUENDB and the power control signal PWRGTB to output a first internal reset signal RI_1. The NAND gate 167 receives the power control signal PWRGTB output from the power control circuit 121 and the reset bar pulse signal RSTBPL2H, and performs a NAND operation on the power control signal PWRGTB and the reset bar pulse signal RSTBPL2H to output a first internal set signal SI_1. The R_S latch 169 generates and outputs the bootup enable signal BOOTUPEN unless the internal reset signal RI is activated during the period when the first internal set signal SI_1 is activated.

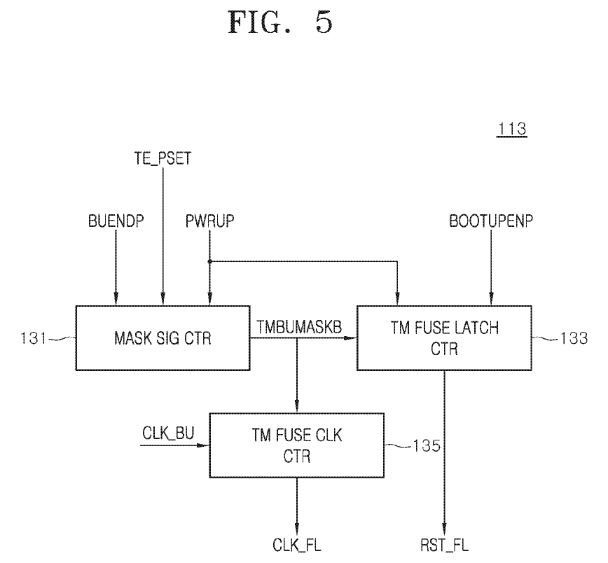

FIG. 5 illustrates a masking control circuit 113 according to an embodiment of the present disclosure, for example as shown in FIG. 2.

As shown in FIG. 5, the masking control circuit 113 includes a masking signal control circuit 131, a test mode fuse latch control circuit 133, and a test mode fuse clock control circuit 135.

The masking signal control circuit 131 generates a masking signal TMBUMASKB when a test set pulse signal TE_PSET is activated during a power-up period when a power-up signal PWRUP is activated to perform a re-bootup operation. The masking signal control circuit 131 deactivates the masking signal TMBUMASKB when the power-up period ends or a bootup end pulse signal BUENDP is activated to end the re-bootup operation.

When the masking signal TMBUMASKB is activated to perform the re-bootup operation, the test mode fuse latch control circuit 133 masks a bootup enable pulse signal BOOTUPENP and the power-up signal PWRUP to deactivate a fuse latch reset signal RST_FL. The test mode fuse latch control circuit 133 determines whether to activate the fuse latch reset signal RST_FL by performing an OR operation on the bootup enable pulse signal BOOTUPENP and the power-up signal PWRUP and performing an AND operation on a result of the OR operation and the masking signal TMBUMASKB. As a result, in an embodiment, when the fuse latch reset signal RST_FL is masked, existing input fuse data FZDATA_I<0:13> and bias trim information may be maintained without being reset.

The test mode fuse latch control circuit 133 generates the fuse latch reset signal RST_FL based on the power up signal PWRUP to perform the bootup operation.

The test mode fuse clock control circuit 135 outputs a bootup clock signal CLK_BU as a fuse latch clock signal CLK_FL to perform the bootup operation.

The test mode fuse clock control circuit 135 masks the fuse latch clock signal CLK_FL when the masking signal TMBUMASKB is activated to perform the re-bootup operation. For example, the test mode fuse clock control circuit 135 masks the fuse latch clock signal CLK_FL based on the masking signal TMBUMASKB by performing an AND operation on the bootup clock signal CLK_BU and the masking signal TMBUMASKB.

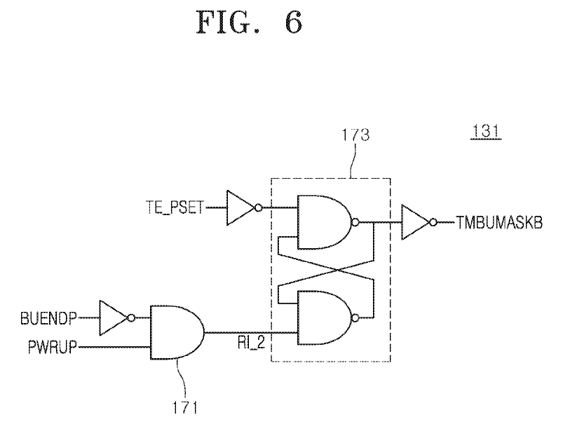

FIG. 6 is a circuit diagram illustrating a masking signal control circuit 131 according to an embodiment of the present disclosure, for example, as shown in FIG. 5.

As shown in FIG. 6, the masking signal control circuit 131 includes an AND gate 171 and an R_S latch 173. The AND gate 171 performs an AND operation on a bootup end pulse signal BUENDP and a power-up signal PWRUP to generate a second internal reset signal RI_2. The R_S latch 173 activates a masking signal TMBUMASKB during a period when a test set pulse signal TE_PSET is activated, and deactivates the masking signal TMBUMASKB when the second internal reset signal RI_2 is activated.

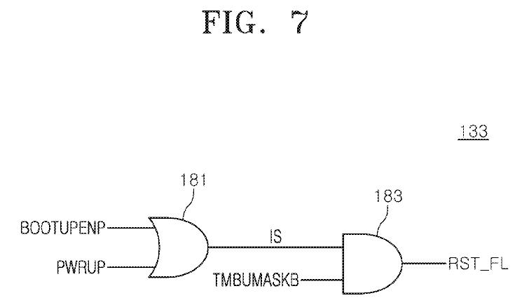

FIG. 7 is a circuit diagram illustrating a test mode fuse latch control circuit 133 according to an embodiment of the present disclosure, for example, as shown in FIG. 5.

As shown in FIG. 7, the test mode fuse latch control circuit 133 includes an OR gate 181 and an AND gate 183. The OR gate 181 performs an OR operation on a bootup enable pulse signal BOOTUPENP and a power up signal PWRUP to generate an internal signal IS. The AND gate 183 performs a masking operation by performing an AND operation on the internal signal IS and a masking signal TMBUMASKB to output a fuse latch reset signal RST_FL.

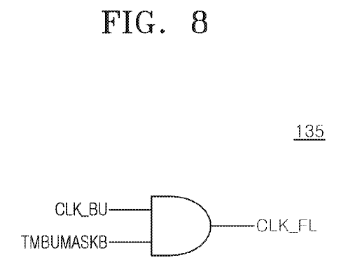

FIG. 8 is a circuit diagram illustrating a test mode fuse clock control circuit 135 according to an embodiment of the present disclosure, for example, as shown in FIG. 5.

As shown in FIG. 8, the test mode fuse clock control circuit 135 generates a fuse latch clock signal CLK_FL based on a masking signal TMBUMASKB deactivated at a logic high level and a bootup clock signal CLK_BU to perform a bootup operation. The test mode fuse clock control circuit 135 masks the fuse latch clock signal CLK_FL when the masking signal TMBUMASKB is activated to perform a re-bootup operation. For example, the test mode fuse clock control circuit 135 masks the fuse latch clock signal CLK_FL based on the masking signal TMBUMASKB by performing an AND operation on the bootup clock signal CLK_BU and the masking signal TMBUMASKB.

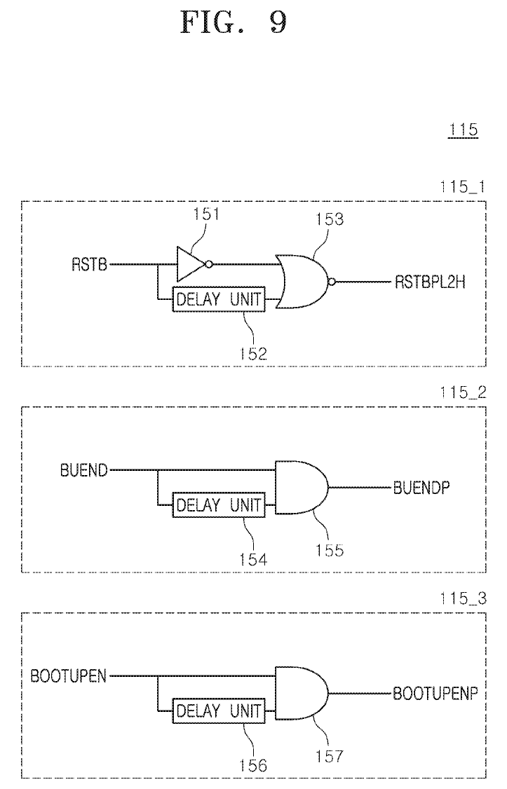

FIG. 9 is a circuit diagram illustrating a pulse generation circuit 115 according to an embodiment of the present disclosure, for example, as shown in FIG. 2.

As shown in FIG. 9, the pulse generation circuit 115 includes a reset bar signal pulse generation circuit 115_1, a bootup end signal pulse generation circuit 115_2, and a bootup enable signal pulse generation circuit 115_3.

The reset bar signal pulse generation circuit 115_1 includes an inverter 151, a delay unit 152, and a NOR gate 153. The inverter 151 inversely buffers a reset bar signal RSTB and outputs an inversely buffered signal of the reset bar signal RSTB. The delay unit 152 delays the reset bar signal RSTB to output a delayed reset bar signal. The NOR gate 153 performs a NOR operation on an output signal of the inverter 151 and an output signal of the delay unit 153 and outputs a reset bar pulse signal RSTBPL2H. In this case, the reset bar pulse signal RSTBPL2H may be defined as a pulse signal output in response only when the reset bar signal RSTB transitions from a logic low level to a logic high level.

The bootup end signal pulse generation circuit 115_2 includes a delay unit 154 and an AND gate 155. The delay unit 154 delays a bootup end signal BUEND and outputs a delayed bootup end signal. The AND gate 155 performs an AND operation on the bootup end signal BUEND and the delayed bootup end signal and outputs a bootup end pulse signal BUENDP.

The bootup enable signal pulse generation circuit 115_3 includes a delay unit 156 and an AND gate 157. The delay unit 156 delays the bootup enable signal BOOTUPEN and outputs a delayed bootup enable signal. The AND gate 157 performs an AND operation on the bootup enable signal BOOTUPEN and the delayed bootup enable signal and outputs a bootup enable pulse signal BOOTUPENP.

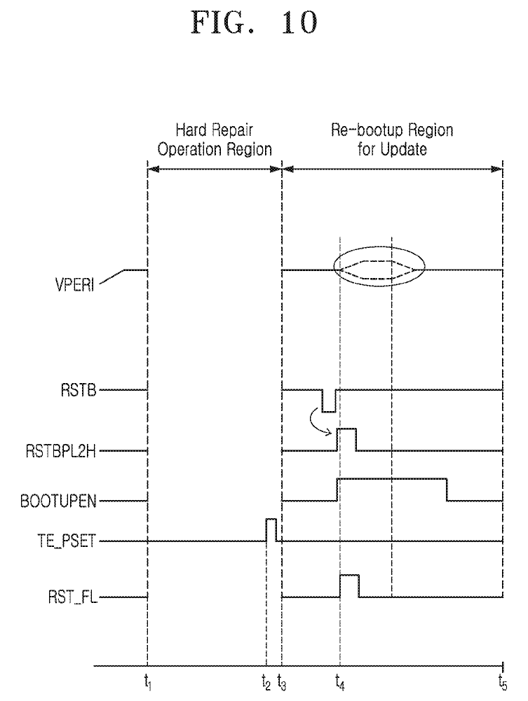

FIG. 10 is a timing diagram illustrating when a masking operation is not performed for a fuse latch reset signal RST_FL in a re-bootup operation.

As shown in FIG. 10, when the re-bootup operation is performed in a re-bootup region t3-t5 following a hard repair operation performed in a hard repair operation region t1-t3, bias trim information on an internal voltage VPERI is reset due to the fuse latch reset signal RST_FL to be in a non-trimming state. As described above, when the re-bootup operation is performed in a state in which the voltage level of the internal voltage VPERI is not guaranteed, it might not be guaranteed that the corresponding re-bootup operation proceeds normally. More specifically, a test set pulse signal TE_PSET is generated at the end t2 of the hard repair operation region to enter the re-bootup operation region, and then a bootup enable signal BOOTUPEN and a reset bar pulse signal RSTBPL2H transition to logic high levels to start the re-bootup operation. A fuse latch reset signal RST_FL is generated at the subsequent re-bootup operation time t4 to reset bias trim information of the internal voltage VPERI. As a result, because the re-bootup operation can be guaranteed to operate normally only when the bias trim information of the internal voltage VPERI is maintained, it may be necessary to mask the fuse latch reset signal RST_FL with respect to the internal voltage VPERI during the re-bootup operation following the hard repair operation. RSTB may be defined as a signal that generates the reset bar pulse signal (RSTBPL2H) and specifies the start timing of the re-bootup operation.

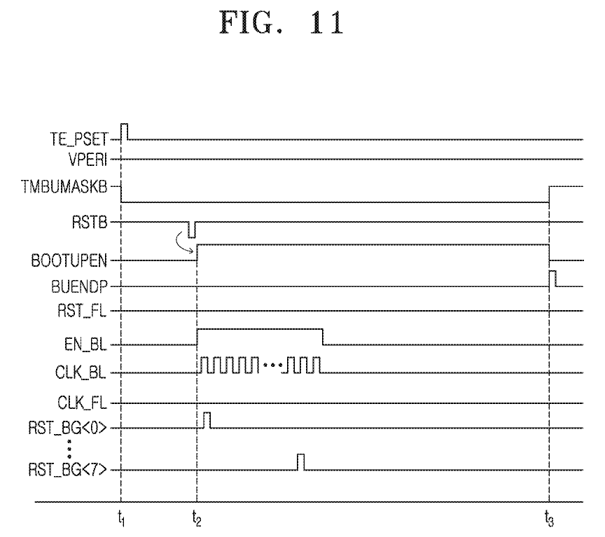

FIG. 11 is a timing diagram during an operation of a semiconductor device according to an embodiment of the present disclosure.

As shown in FIG. 11, apart from the case in FIG. 10, in the re-bootup operation in which the masking function for a fuse latch reset signal RST_FL and a fuse latch clock signal CLK_FL is added, the bias trim information of an internal voltage VPERI may be maintained. Accordingly, in an embodiment, a stable re-bootup operation may be guaranteed based on the internal voltage VPERI having a voltage level that is guaranteed. More specifically, not only a test set pulse signal TE_PSET is generated at the end of the hard repair operation region, but also a masking signal TMBUMASKB is generated based on the generation of the test set pulse signal TE_PSET at a time t1, and the re-bootup operation region is entered. Thereafter, a reset bar pulse signal RSTBPL2H transitions to a logic high level based on a reset bar signal RSTB, and then a bootup enable signal BOOTUPEN is activated at a time t2 based on the reset bar pulse signal RSTBPL2H. At this time, the fuse latch reset signal RST_FL is masked by the masking signal TMBUMASKB, and thus does not affect the internal voltage VPERI. As a result, the bias trim information of the internal voltage VPERI may be maintained. In addition, the fuse latch clock signal CLK_FL is also masked by the masking signal TMBUMASKB to deactivate the fuse latch clock signal CLK_FL. When a bootup end pulse signal BUENDP is activated to end the re-bootup operation at the end time t3 of such a series of processes, the bootup enable signal BOOTUPEN is deactivated through a bootup signal generation circuit 123.

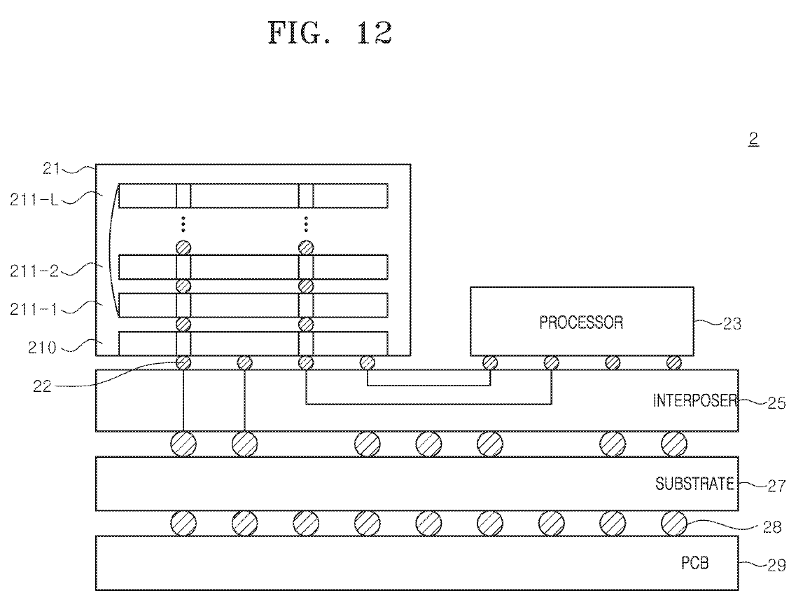

FIG. 12 is a block diagram illustrating a stacked memory system 2 according to an embodiment of the present disclosure.

As shown in FIG. 12, the memory system 2 includes a printed circuit board (PCB) 29, a substrate 27, an interposer 25, a memory device 21, and a processor 23.

The printed circuit board 29 connects various electronic components to each other to form electronic circuits. The electronic circuits include the memory system 2. A copper (Cu) layer, a solder mask, a silk screen, and so forth are formed on the printed circuit board 29. Circuit paths that transmit or transfer signals or power are formed in the copper (Cu) layer. In an embodiment, the solder mask prevents or mitigates damage to the circuits and protects a specific region where components are soldered. The silk screen indicates location or information for the electronic components as characters or symbols printed on a surface of the printed circuit board 29.

The substrate 27 is disposed over the printed circuit board 29 with bump pads therebetween, for example, bump pads 28 that mechanically support the interposer 25, the memory device 21, and the processor 23. The substrate 27 functions as a physical base for the printed circuit board 21 and is an insulator. The substrate 27 may include materials such as FR4 that is an insulator made of fiberglass and epoxy resin, ceramics that can withstand high temperatures, have appropriate thermal conductivity properties, and are used in high-frequency circuits, polyimide that is used as a basic material for flexible PCBs due to flexible characteristics, and the like.

The interposer 25 is disposed over the substrate 27 with bump pads 28 therebetween and includes wiring that connects electronic components, for example, the memory device 21 and the processor 23, that have form factors or pin arrangements do not match or have different spacing. The interposer 25 converts signals from different interfaces.

The memory device 21 is disposed over the interposer 25 with pads therebetween, for example, micro bump pads 22. The memory device 21 stores data received from the processor 23 or outputs the stored data to the processor 23 under control of the processor 23. The memory device 21 includes a base die 210 and a plurality of core dies 211-1 to 211-L, where L is an integer greater than 1. The core dies 211-1 to 211-L are stacked over the base die 210 with micro bump pads therebetween. The base die 210 and the core dies 211-1 to 211-L are vertically connected to each other using through vias and micro bump pads. The base die 210 controls efficient data transmission between the processor 23 and the core dies 211-1 to 211-L.

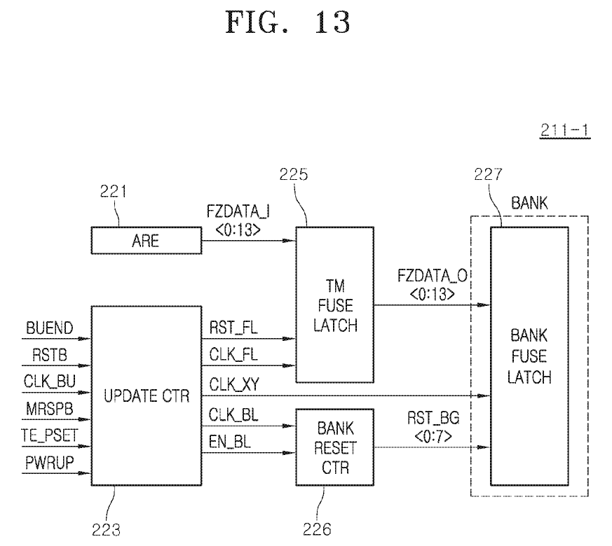

FIG. 13 illustrates a first core die 211-1, which is one of a plurality of core dies 211-1 to 211-L according to an embodiment of the present disclosure, for example, included in a memory system 2 in FIG. 12.

As shown in FIG. 13, the first core die 211-1 includes a fuse array 221, an update control circuit 223, a test mode fuse latch 225, a bank reset control circuit 226, and a bank fuse latch 227. The first core die 211-1 performs a bootup operation and a re-bootup operation.

The fuse array 221 is electrically connected to the test mode fuse latch 225 and outputs input fuse data FZDATA_I<0:13> to the test mode fuse latch 225. Here, the input fuse data FZDATA_I<0:13> may be trimming information on a voltage level of an internal voltage VPERI. The input fuse data FZDATA_I<0:13> may be set to have a logic bit set corresponding to a certain voltage level to trim the internal voltage VPERI to the certain voltage level. For example, a first logic bit set of the input fuse data FZDATA_I<0:13> may correspond to a first voltage level, and a second logic bit set of the input fuse data FZDATA_I<0:13> may correspond to a second voltage level. The fuse array 221 includes a plurality of fuse cell arrays (FSAs). The fuse cell array includes a plurality of fuses FS. Here, the fuse array 221 includes electrically programmable e-fuses. The input fuse data FZDATA_I<0:13> may be a signal including repair information for row-series and column-series as well as the trimming information for adjusting the voltage level of the internal voltage.

The update control circuit 223 performs a bootup operation. The bootup operation includes an operation of generating a fuse latch clock signal CLK_FL and a fuse latch reset signal RST_FL. Here, the fuse latch reset signal RST_FL is a signal generated at the start of a re-bootup operation for updating the information ruptured by a hard repair, and may be a signal for resetting the test mode fuse latch 225 containing the existing input fuse data FZDATA_I<0:13> and bias trim information. In addition, the fuse latch clock signal CLK_FL may be a clock signal used when updating the existing input fuse data FZDATA_I<0:13> and the bias trim information. The update control circuit 223 generates the fuse latch reset signal RST_FL based on a power-up signal PRWUP. The update control circuit 223 generates the fuse latch clock signal CLK_FL based on a bootup clock signal CLK_BU. The update control circuit 223 delays the bootup clock signal CLK_BU to generate the fuse latch clock signal CLK_FL. The update control circuit 223 outputs the fuse latch reset signal RST_FL and the fuse latch clock signal CLK_FL to the electrically connected test mode fuse latch 225.

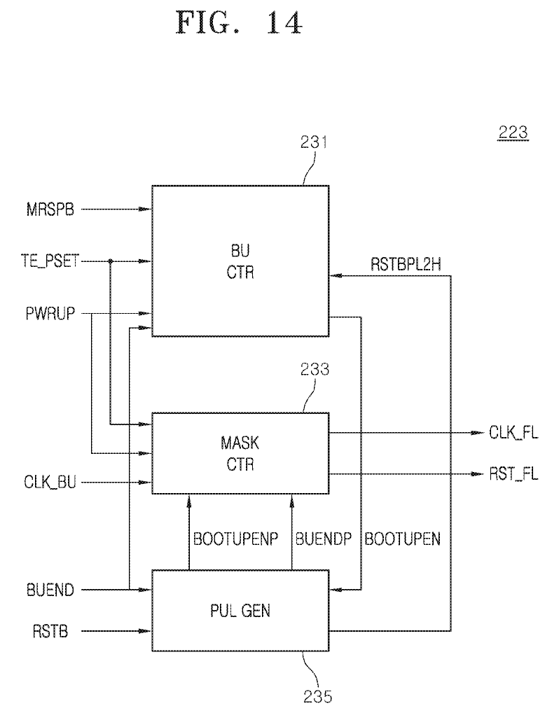

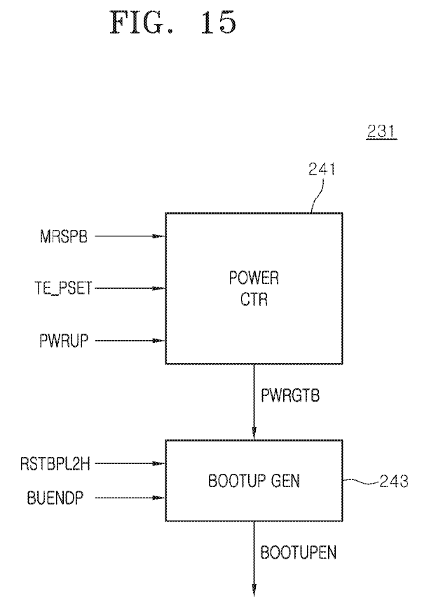

The update control circuit 223 activates the fuse latch reset signal RST_FL during a power-up period in which the power-up signal PWRUP is activated. The update control circuit 223 performs a bootup end operation based on a mode register set bar pulse signal MRSPB and a bootup end signal BUEND. The update control circuit 223 deactivates a power control signal (e.g., PWRGTB in FIG. 15), which is a signal necessary for the bootup operation, based on the mode register set bar pulse signal MRSPB, and deactivates a bootup enable signal (e.g., BOOTUPEN in FIG. 14) generated based on the power control signal PWRGTB, thereby ending the bootup operation. Here, the mode register set bar pulse signal MRSPB may be a pulse signal output from a mode register set having data on bootup operation control.

The update control circuit 223 performs a re-bootup operation following a hard-repair operation. The hard-repair operation refers to a post package repair operation in which the effect of repair is permanently maintained once repaired. The re-bootup operation may be defined as an operation of updating row-series and column-series information ruptured by the hard-repair operation after the hard-repair operation is completed. The update control circuit 223 performs a masking operation on the fuse latch clock signal CLK_FL and the fuse latch reset signal RST_FL for the re-bootup operation. The update control circuit 223 masks the fuse latch reset signal RST_FL based on a reset bar signal RSTB and a test set pulse signal TE_PSET during the power-up period in which the power-up signal PWRUP is activated for the re-bootup operation. The fuse latch reset signal RST_FL is a signal generated at the start of the re-bootup operation for updating information ruptured by the hard-repair, and may be a signal for resetting the test mode fuse latch 225 containing the existing input fuse data FZDATA_I<0:13> and bias trim information. The update control circuit 223 masks the fuse latch clock signal CLK_FL based on the test set pulse signal TE_PSET and a bootup clock signal CLK_BU during the power-up period for the re-bootup operation. Here, the power-up signal PWRUP may refer to a signal activated when the voltage level of the power supply voltage VDD reaches a voltage level of a certain target level.

After performing the re-bootup operation, the update control circuit 223 performs a re-bootup end operation of ending the re-bootup operation and the masking operation on the fuse latch clock signal CLK_FL and the fuse latch reset signal RST_FL based on the mode register set bar pulse signal MRSPB and the bootup end signal BUEND. More specifically, the update control circuit 223 deactivates the power control signal PWRGTB, which is a signal necessary for the re-bootup operation, based on the mode register set bar pulse signal MRSPB, deactivates the bootup enable signal BOOTUPEN generated based on the power control signal PWRGTB, and deactivates the masking signal TMBUMASKB generated based on the bootup enable signal BOOTUPEN, thereby ending the re-bootup operation. The update control circuit 223 ends the re-bootup operation by deactivating the bootup enable signal BOOTUPEN and the masking signal TMBUMASKB based on the bootup end signal BUEND.

The update control circuit 223 generates a bank fuse latch enable signal EN_BL and a bank fuse latch clock signal CLK_BL based on the bootup clock signal CLK_BU. The update control circuit 223 generates a row column clock signal CLK_XY based on the bootup clock signal CLK_BU. The row column clock signal CLK_XY may be defined as a signal for strobing row-series and the column-series repair data included in the output fuse data FZDATA_O<0:13>. The update control circuit 223 outputs the row column clock signal CLK_XY to the electrically connected bank fuse latch 227.

The test mode fuse latch 225 is electrically connected to the fuse array 221 and the update control circuit 223, receives the input fuse data FZDATA_I<0:13> from the fuse array 221, and receives the fuse reset signal RST_FL and the fuse latch clock signal CLK_FL from the update control circuit 223. The test mode fuse latch 225 latches the input fuse data FZDATA_I<0:13> based on the fuse reset signal RST_FL and the fuse latch clock signal CLK_FL, and outputs the latched input fuse data FZDATA_I<0:13> as output fuse data FZDATA_O<0:13>. The test mode fuse latch 225 may be located in a peripheral region. The test mode fuse latch 225 resets the input fuse data FZDATA_I<0:13> and bias trim information based on the fuse reset signal RST_FL and the fuse latch clock signal CLK_FL. The test mode fuse latch 225 receives and stores the input fuse data FZDATA_I<0:13> that is trimming information on the internal voltage VPERI. The test mode fuse latch 225 outputs the latched input fuse data FZDATA_I<0:13> as the output fuse data FZDATA_O<0:13>.

The bank reset control circuit 226 is electrically connected to the update control circuit 223 and receives the bank fuse latch clock signal CLK_BL and the bank fuse latch enable signal EN_BL from the update control circuit 223. The bank reset control circuit 226 generates a bank fuse latch reset signal RST_BG<0:7> based on the bank fuse latch clock signal CLK_BL and the bank fuse latch enable signal EN_BL. The bank fuse latch clock signal CLK_BL may be defined as a signal for controlling reset of the bank fuse latch 227 for each bank group. The bank fuse latch enable signal EN_BL may be defined as a flag signal for notifying that a certain period corresponds to a period in which column-series and row-series trimming information on the bank fuse latch 227 is updated, among periods in which the re-bootup operation and the bootup operation are performed. The bank reset control circuit 226 may be located in the peripheral region. The bank reset control circuit 226 generates the bank fuse latch reset signal RST_BG<0:7> based on the bank fuse latch clock signal CLK_BL during a period in which the trimming information is updated based on the bank fuse latch enable signal EN_BL. The bank fuse latch reset signal RST_BG<0:7> is allocated and output for each bank group. The bank fuse latch reset signal RST_BG<0:7> is sequentially output to a plurality of fuse latches in the bank fuse latch 227 located in a bank region. When a reset operation is performed through the bank fuse latch reset signal RST_BG<0:7> that is sequentially output, instantaneous current consumption may be reduced compared to when the reset operations for updating the plurality of fuse latches are simultaneously performed.

The bank fuse latch 227 is electrically connected to the update control circuit 223, the test mode fuse latch 225, and the bank reset control circuit 226, receives the row column clock signal CLK_XY from the update control circuit 223, receives the output fuse data FZDATA_O<0:13> from the test mode fuse latch 225, and receives the bank fuse latch reset signal RST_BG<0:7> from the bank reset control circuit 226. The plurality of fuse latches in the bank fuse latch 227 update the output fuse data FZDATA_O<0:13> with repair information based on the row column clock signal CLK_XY and the bank fuse latch reset signal RST_BG<0:7>. The plurality of fuse latches in the bank fuse latch 227 may be located in the bank region. The plurality of fuse latches in the bank fuse latch 227 individually perform a reset operation according to whether the bank fuse latch reset signal RST_BG<0:7> is activated. The row column clock signal CLK_XY is generated in the update control circuit 223 based on the bootup clock signal CLK_BU. The row column clock signal CLK_XY may be defined as a signal for strobing row-series and column-series repair data included in the output fuse data FZDATA_O<0:13>.

FIG. 14 illustrates an update control circuit 223 according to an embodiment of the present disclosure, for example as shown in FIG. 13.

As shown in FIG. 14, the update control circuit 223 includes a bootup control circuit 231, a masking control circuit 233, and a pulse generation circuit 235.

The bootup control circuit 231 generates a bootup enable signal BOOTUPEN based on a test set pulse signal TE_PSET and a reset bar pulse signal RSTBPL2H to perform a re-bootup operation during a power-up period. The bootup control circuit 231 deactivates the bootup enable signal BOOTUPEN when a mode register set bar pulse signal MRSPB is activated, thereby preventing a masking operation for the fuse latch reset signal RST_FL by the bootup enable pulse signal BOOTUPENP from being performed. When the bootup end signal BUEND is activated, the bootup control circuit 231 deactivates the bootup enable signal BOOTUPEN, thereby preventing the masking operation on the fuse latch reset signal RST_FL by a bootup enable pulse signal BOOTUPENP from being performed. Therefore, the re-bootup end operation may be performed.

The masking control circuit 233 generates the fuse latch reset signal RST_FL based on a power-up signal PWRUP for the bootup operation. The masking control circuit 233 generates a fuse latch clock signal CLK_FL based on a bootup clock signal CLK_BU for the bootup operation.

The masking control circuit 233 masks the fuse latch reset signal RST_FL when the test set pulse signal TE_PSET and the bootup enable pulse signal BOOTUPENP are applied during the power-up period to perform the re-bootup operation. When the bootup enable pulse signal BOOTUPENP is applied during the power-up period to perform the re-bootup operation, the masking control circuit 233 masks the bootup clock signal CLK_BU to deactivate the fuse latch clock signal CLK_FL.

The pulse generation circuit 235 outputs the bootup end signal BUEND, a reset bar signal RSTB, and the bootup enable signal BOOTUPEN as the bootup end pulse signal BUENDP, the reset bar pulse signal RSTBPL2H, and the bootup enable pulse signal BOOTUPENP, that are pulse signals, respectively.

FIG. 15 illustrates a bootup control circuit 231 according to an embodiment of the present disclosure, for example, as shown in FIG. 14.

As shown in FIG. 15, the bootup control circuit 231 includes a power control circuit 241 and a bootup signal generation circuit 243. The power control circuit 241 generates a power control signal PWRGTB when a test set pulse signal TE_PSET is activated during a power-up period in which a power-up signal PWRUP is activated for a re-bootup operation or a bootup operation. The bootup signal generation circuit 243 generates a bootup enable signal BOOTUPEN when a reset bar pulse signal RSTBPL2H is activated during a period when the power control signal PWRGTB is activated to perform the re-bootup operation.

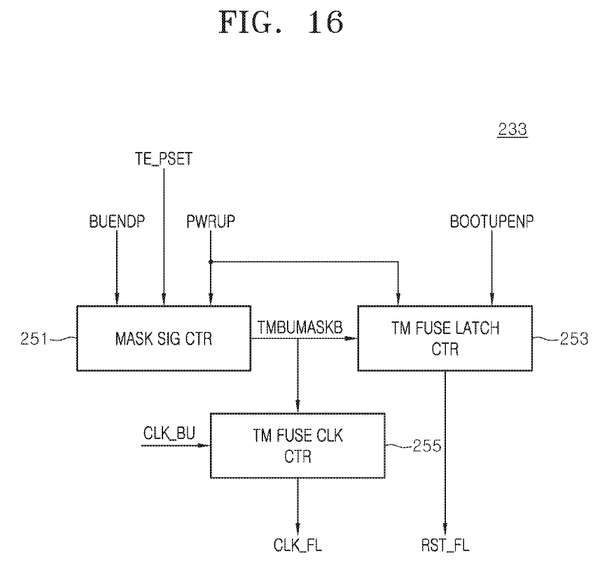

FIG. 16 illustrates a masking control circuit 233 according to an embodiment of the present disclosure, for example, as shown in FIG. 14.

As shown in FIG. 16, the masking control circuit 233 includes a masking signal control circuit 251, a test mode fuse latch control circuit 253, and a test mode fuse clock control circuit 255.

The masking signal control circuit 251 generates a masking signal TMBUMASKB when a test set pulse signal TE_PSET is activated during a power-up period to perform a re-bootup operation. The masking signal control circuit 251 deactivates the masking signal TMBUMASKB when a power-up period ends or a bootup end pulse signal BUENDP is activated to end the re-bootup operation.

The test mode fuse latch control circuit 253 masks a bootup enable pulse signal BOOTUPENP and a power-up signal PWRUP to deactivate the fuse latch reset signal RST_FL when the masking signal TMBUMASKB is activated to perform the re-bootup operation. The test mode fuse latch control circuit 253 determines whether to activate the fuse latch reset signal RST_FL by performing an OR operation on the bootup enable pulse signal BOOTUPENP and the power-up signal PWRUP, and performing an AND operation on the masking signal TMBUMASKB and a result of the OR operation. As a result, when the fuse latch reset signal RST_FL is masked, the existing input fuse data FZDATA_I<0:13> and the bias trim information may be maintained without being reset. The test mode fuse latch control circuit 253 generates the fuse latch reset signal RST_FL based on the power-up signal PWRUP to perform the bootup operation.

The test mode fuse clock control circuit 255 outputs a bootup clock signal CLK_BU as the fuse latch clock signal CLK_FL to perform the bootup operation. The test mode fuse clock control circuit 255 masks the fuse latch clock signal CLK_FL when the masking signal TMBUMASKB is activated to perform the re-bootup operation. In more detail, the test mode fuse clock control circuit 255 masks the fuse latch clock signal CLK_FL based on the masking signal TMBUMASKB by performing an AND operation on the bootup clock signal CLK_BU and the masking signal TMBUMASKB.

As described above, according to an embodiment of the present disclosure, by masking a fuse latch reset signal and a fuse latch clock signal generated during a hard-repair operation, it is possible to maintain the existing bias information on a voltage level of an internal voltage to stably perform a re-bootup operation.

Concepts are disclosed in conjunction with various examples and embodiments. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. The scope of the present disclosure is not limited to the descriptions. All changes within the meaning and range of equivalency of the claims are included within their scope.

what is claimed is:

1. A semiconductor device comprising:
a fuse array configured to output input fuse data for a bootup operation and a re-bootup operation;
an update control circuit configured to generate a bank fuse latch enable signal, a row column clock signal, and a bank fuse latch clock signal based on a bootup clock signal to perform the bootup operation and the re-bootup operation, and mask a fuse latch reset signal and a fuse latch clock signal when a test set pulse signal is activated to perform the re-bootup operation; and
a test mode fuse latch configured to latch the input fuse data based on the fuse latch clock signal and the fuse latch reset signal, and output the latched input fuse data as output fuse data during the bootup operation, wherein input of the input fuse data into the test mode fuse latch is blocked when the fuse latch reset signal and the fuse latch clock signal are masked during the re-bootup operation.

2. The semiconductor device of claim 1, wherein the update control circuit is configured to:
generate the fuse latch clock signal and the fuse latch reset signal based on a power-up signal and a bootup clock signal for the bootup operation, and
end the bootup operation based on a mode register set bar pulse signal and a bootup end signal.

3. The semiconductor device of claim 2, wherein the update control circuit is configured to:
generate the fuse latch reset signal that resets data and bias trim of the test mode fuse latch when a reset bar signal is activated during a power-up period whereby the power-up signal is activated for the bootup operation,
generate the fuse latch clock signal based on the bootup clock signal during the power-up period, and
end the bootup operation based on the mode register set bar pulse signal and the bootup end signal.

4. The semiconductor device of claim 3, wherein the update control circuit comprises:
a masking control circuit configured to generate the fuse latch reset signal and generate the fuse latch clock signal based on the bootup clock signal when the power-up signal is activated for the bootup operation; and
a pulse generation circuit configured to output the bootup end signal and the reset bar signal as a bootup end pulse signal and a reset bar pulse signal, respectively, for the bootup operation.

5. The semiconductor device of claim 4, wherein the masking control circuit masks the fuse latch reset signal when the power-up signal is deactivated to end the bootup operation.

6. The semiconductor device of claim 1, wherein the update control circuit is configured to:
mask the fuse latch reset signal based on the test set pulse signal and a reset bar signal during a power-up period when a power-up signal is activated for the re-bootup operation,
mask the fuse latch clock signal based on the test set pulse signal and a bootup clock signal during the power-up period, and
end the re-bootup operation based on a mode register set bar pulse signal and a bootup end signal.

7. The semiconductor device of claim 6, wherein the update control circuit comprises:
a bootup control circuit configured to generate a bootup enable signal based on the test set pulse signal and a reset bar pulse signal during the power-up period for the re-bootup operation;
a masking control circuit configured to mask the fuse latch reset signal based on the test set pulse signal and a bootup enable pulse signal during the power-up period, and mask the fuse latch clock signal based on the bootup enable pulse signal and the fuse latch clock signal during the power-up period for the re-bootup operation; and
a pulse generation circuit configured to output the bootup end signal, the reset bar signal, and the bootup enable signal as a bootup end pulse signal, the reset bar pulse signal, and the bootup enable pulse signal, that are pulse signals, respectively, for the re-bootup operation.

8. The semiconductor device of claim 7, wherein the bootup control circuit comprises:
a power control circuit configured to generate a power control signal when the test set pulse signal is activated during the power-up period for the re-bootup operation; and
a bootup signal generation circuit configured to generate the bootup enable signal when the reset bar pulse signal is activated in a period when the power control signal is activated for the re-bootup operation.

9. The semiconductor device of claim 8, wherein the power control circuit deactivates the power control signal when the mode register set bar pulse signal is activated to end the re-bootup operation.

10. The semiconductor device of claim 8, wherein the bootup signal generation circuit deactivates the bootup enable signal when the bootup end pulse signal is activated to end the re-bootup operation.

11. The semiconductor device of claim 7, wherein the masking control circuit comprises:
a masking signal control circuit configured to generate a masking signal when the test set pulse signal is activated during the power-up period for the re-bootup operation;
a test mode fuse latch control circuit configured to mask the bootup enable pulse signal and the power-up signal to deactivate the fuse latch reset signal when the masking signal is activated for the re-bootup operation; and
a test mode fuse clock control circuit configured to mask the fuse latch clock signal when the masking signal is activated and the bootup clock signal is activated for the re-bootup operation.

12. The semiconductor device of claim 11, wherein the masking signal control circuit deactivates the masking signal when the power-up period ends or the bootup end pulse signal is activated to end the re-bootup operation.

13. The semiconductor device of claim 7, wherein the update control circuit deactivates the bootup enable signal when the bootup end signal is activated or the mode register set bar pulse signal is activated to end the re-bootup operation.

14. The semiconductor device of claim 1, wherein each of the input fuse data and the output fuse data includes trimming information for adjusting a voltage level of an internal voltage and row-series and column-series repair information.

15. The semiconductor device of claim 1, further comprising a bank reset control circuit configured to generate a bank fuse latch reset signal based on the bank fuse latch clock signal and the bank fuse latch enable signal.

16. The semiconductor device of claim 15, further comprising a bank fuse latch including a plurality of fuse latches and configured to sequentially update the output fuse data to the plurality of fuse latches with repair information based on the row column clock signal and the bank fuse latch reset signal.

17. A memory system comprising:
an interposer stacked over a substrate; and
a memory device and a processor that are stacked over the interposer and connected to each other through wiring formed in the interposer,
wherein the memory device comprises a base die and a plurality of core dies,
wherein each of the plurality of core dies receives a control signal from the base die to perform a bootup operation and a re-bootup operation, and
wherein each of the plurality of core dies masks a signal for resetting trimming information of an internal voltage during the re-bootup operation to maintain a voltage level of the internal voltage.

18. The memory system of claim 17, wherein each of the plurality of core dies comprises:
a fuse array configured to output input fuse data for the bootup operation and the re-bootup operation;
an update control circuit configured to generate a bank fuse latch enable signal, a row column clock signal, and a bank fuse latch clock signal based on a bootup clock signal to perform the bootup operation and the re-bootup operation, and mask a fuse latch reset signal and a fuse latch clock signal when a test set pulse signal is activated to perform the re-bootup operation; and
a test mode fuse latch configured to latch the input fuse data based on the fuse latch clock signal and the fuse latch reset signal, and output the latched input fuse data as output fuse data during the bootup operation, wherein input of the input fuse data into the test mode fuse latch is blocked when the fuse latch reset signal and the fuse latch clock signal are masked during the re-bootup operation.

19. The memory system of claim 18, wherein the update control circuit is configured to:
generate the fuse latch clock signal and the fuse latch reset signal based on a power-up signal and a bootup clock signal for the bootup operation, and
end the bootup operation based on a mode register set bar pulse signal and a bootup end signal.

20. The memory system of claim 19, wherein the update control circuit is configured to:
generate the fuse latch reset signal that resets data and bias trim of the test mode fuse latch when a reset bar signal is activated during a power-up period whereby the power-up signal is activated for the bootup operation,
generate the fuse latch clock signal based on the bootup clock signal during the power-up period, and
end the bootup operation based on the mode register set bar pulse signal and the bootup end signal.

21. The memory system of claim 20, wherein the update control circuit comprises:
a masking control circuit configured to generate the fuse latch reset signal when the power-up signal is activated for the bootup operation and generate the fuse latch clock signal based on the bootup clock signal; and
a pulse generation circuit configured to output the bootup end signal and the reset bar signal as a bootup end pulse signal and a reset bar pulse signal, which are pulse signals, respectively, for the bootup operation.

22. The memory system of claim 21, wherein the masking control circuit masks the fuse latch reset signal when the power-up signal is deactivated to end the bootup operation.

23. The memory system of claim 18, wherein the update control circuit is configured to:
mask the fuse latch reset signal based on the test set pulse signal and a reset bar signal during a power-up period when a power-up signal is activated for the re-bootup operation,
mask the fuse latch clock signal based on the test set pulse signal and the bootup clock signal during the power-up period, and
end the re-bootup operation based on a mode register set bar pulse signal and a bootup end signal.

24. The memory system of claim 23, wherein the update control circuit comprises:
a bootup control circuit configured to generate a bootup enable signal based on the test set pulse signal and a reset bar pulse signal during the power-up period;
a masking control circuit configured to mask the fuse latch reset signal based on the test set pulse signal and a bootup enable pulse signal during the power-up period, and mask the fuse latch clock signal based on the bootup enable pulse signal and the fuse latch clock signal during the power-up period; and
a pulse generation circuit configured to output the bootup end signal, the reset bar signal, and the bootup enable signal as a bootup end pulse signal, the reset bar pulse signal, and the bootup enable pulse signal, that are pulse signals, respectively.

25. The memory system of claim 24, wherein the bootup control circuit comprises:
a power control circuit configured to generate a power control signal when the test set pulse signal is activated during the power-up period for the re-bootup operation; and
a bootup signal generation circuit configured to generate the bootup enable signal when the reset bar pulse signal is activated in a period when the power control signal is activated for the re-bootup operation.

26. The memory system of claim 25, wherein the power control circuit deactivates the power control signal when the mode register set bar pulse signal is activated to end the re-bootup operation.

27. The memory system of claim 25, wherein the bootup signal generation circuit deactivates the bootup enable signal when the bootup end pulse signal is activated to end the re-bootup operation.

28. The memory system of claim 24, wherein the masking control circuit comprises:
a masking signal control circuit configured to generate a masking signal when the test set pulse signal is activated during the power-up period for the re-bootup operation;
a test mode fuse latch control circuit configured to mask the bootup enable pulse signal and the power-up signal to deactivate the fuse latch reset signal when the masking signal is activated for the re-bootup operation; and
a test mode fuse clock control circuit configured to mask the fuse latch clock signal when the masking signal is activated and the bootup clock signal is activated for the re-bootup operation.

29. The memory system of claim 28, wherein the masking signal control circuit deactivates the masking signal when the power-up period ends or the bootup end pulse signal is activated to end the re-bootup operation.

30. The memory system of claim 24, wherein the update control circuit deactivates the bootup enable signal when the bootup end signal is activated or the mode register set bar pulse signal is activated to end the re-bootup operation.

31. The memory system of claim 18, wherein each of the input fuse data and the output fuse data includes trimming information for adjusting a voltage level of an internal voltage and row-series and column-series repair information.

32. The memory system of claim 18, further comprising a bank reset control circuit configured to generate a bank fuse latch reset signal based on the bank fuse latch clock signal and the bank fuse latch enable signal.

33. The memory system of claim 32, further comprising a bank fuse latch including a plurality of fuse latches and configured to sequentially update the output fuse data to the plurality of fuse latches with repair information based on the row column clock signal and the bank fuse latch reset signal.
